(19) United States
(12) Patent Application Publication
(10) Pub. No.: US 2025/0199098 A1
(43) Pub. Date: Jun. 19, 2025

(54) MAGNETIC VALVE AND SYSTEM INCLUDING MAGNETIC VALVE

(71) Applicant: KONINKLIJKE PHILIPS N.V., EINDHOVEN (NL)

(72) Inventors: Peter FORTHMANN, Sandesneben (DE); Steven Joseph GALIOTO, Waterford, NY (US); Tom Mancuso, Hamburg (DE); Mike QUAGLIANA, Latham, NY (US); Kevin GRACE, Latham, NY (US); John Arthur URBAHN, Saratoga Springs, NY (US)

(21) Appl. No.: 18/851,762

(22) PCT Filed: Mar. 28, 2023
(86) PCT No.: PCT/EP2023/057889

§ 371 Date: Sep. 27, 2024

Related U.S. Application Data
(60) Provisional application No. 63/325,628, filed on Mar. 31, 2022.

(51) Int. Cl. G01R 33/38; F16K 31/06; G01R 33/3815

(52) U.S. Cl. CPC G01R 33/3804; F16K 31/0662; G01R 33/3815

(57) ABSTRACT

A magnetic valve controls fluid flow through a tube. The valve includes a first diode and a first solenoid connected between first and second terminals; a second diode and a second solenoid connected between the first and second terminals in parallel, the second diode being antiparallel to the first diode; and a ferrous ball configured to move between open and closed positions. The first solenoid generates a first magnetic field in response to a control signal having a first polarity applied to the first and second terminals, causing the ferrous ball to move toward the first solenoid into the open position enabling fluid flow, and the second solenoid generates a second magnetic field in response to the control signal having a second polarity, causing the ferrous ball to move toward the second solenoid into the closed position blocking fluid flow, where the second polarity is opposite the first polarity.

### BACKGROUND

Superconducting magnets may be used in systems that require strong magnetic fields, such as magnetic resonance (MR) imaging and nuclear magnetic resonance (NMR) spectrometry, for example. The superconducting magnets include one or more electrically conductive magnet coils formed by superconducting wire. To realize superconductivity, the magnet is maintained in a cryogenic environment at a temperature near absolute zero during operation. In the superconducting state, the magnet coils are referred to as superconducting coils, which effectively have no electrical resistance, and therefore conduct much larger electric currents to create the strong magnetic fields for the MR imaging. Operation of a superconducting magnet in the superconducting state may be referred to as persistent current mode. The persistent current mode is the state in which an electrical circuit (e.g., including superconducting coils) carries electrical current substantially indefinitely and without the need for an external power source due to the absence of electrical resistance.

To operate in the persistent current mode, the superconducting magnet is initially cooled to the superconducting state, and ramped to the operating current. Since current cannot simply be injected into a superconducting circuit due to the absence of electrical resistance, a part of the superconducting circuit, referred to as a magnet persistent current switch (PCS), is heated so that it develops electrical resistance, referred to as the normal state or resistive state. Then, voltage may be applied across the magnet PCS in order to inject current into the magnet coils. When the voltage is applied to the magnet PCS in its normal state, most of the current will flow into the magnet coils, although a small current flows through the now resistive wires of the magnet PCS. Applying heat to the PCS and generating the current through it cause the magnet PCS to generate heat. A low temperature cooling system (cryostat), which cools the superconducting coils, cannot cope with the additional heat generated by the magnet PCS. Therefore, the magnetic PCS is thermally decoupled from the cold mass during ramping, where flow of coolant to the magnet PCS may be interrupted using a magnetically actuated valve, for example.

Conventional magnetically actuated valves incorporate at least two actuator coils that can pull in either direction, and two pairs of electrical wires for driving each of the two actuator coils, respectively. These electrical wires must be fed into the cryostat and routed inside the superconducting magnet, which is problematic. For example, the electrical wires are necessarily routed into the super cooled magnet from the exterior environment at room temperature. Since the electrical wires are good thermal conductors, the room temperature heat will creep through them into the cryostat, presenting heat leaks. Therefore, reducing the number of electrical wires would reduce the static heat load on the cryostat. Since the superconducting magnet must operate at or below a cryogenic temperature, e.g., 4 Kelvin (K), even miniscule amounts of heat produced in electrical wires must be compensated for. Also, routing the electrical wires in the magnet is expensive and difficult. That is, the electrical wires are screened with reflective material and staked to a first stage of a cold head of the cooling system, for example, to channel away the brunt of the incoming heat load. Also, the number of electrical wires directly affects the connector pin count. The more electrical wires there are increases the connector pin count, making fewer of the limited number of connector pins available

Accordingly, there is a need for a cooling system that allows the temperature of a magnet PCS to quickly rise and fall as desired, using fewer electrical wires to avoid straining the cooling system for the superconducting coils.

### SUMMARY

According to a representative embodiment, a magnetic valve integrated with a fluid tube is provided for controlling flow of a fluid through the fluid tube. The magnetic valve includes comprising a first diode and a first solenoid connected between a first terminal and a second terminal of the magnetic valve; a second diode and a second solenoid connected between the first terminal and the second terminal in parallel with the first diode and the first solenoid, where the second diode is arranged antiparallel to the first diode; and a ferromagnetic ball configured to move between an open position, enabling flow of the fluid through the fluid tube, and a closed position, blocking flow of the fluid through the fluid tube. The first solenoid is configured to generate a first magnetic field in response to a control signal having a first polarity being applied to the first and second terminals, causing the ferrous ball to move toward the first solenoid into the open position, and the second solenoid is configured to generate a second magnetic field in response to the control signal having a second polarity being applied to the first and second terminals, causing the ferrous ball to move toward the second solenoid into the closed position, where the second polarity is opposite to the first polarity of the control signal.

According to another representative embodiment, a magnetic resonance (MR) imaging system includes a superconducting magnet system configured to provide an MR magnetic field to enable MR imaging, a magnetic valve, and a control circuit. The superconducting magnet system includes magnet coils configured to generate the MR magnetic field in a superconducting state, a magnet persistent current switch (PCS) configured to enter a normal state during ramping of the magnet coils to an operating current in the superconducting state, where a temperature of the magnet PCS increases in the normal state, and a cryostat configured to provide a cryogenic temperature to the magnet coils and the magnet PCS, where the cryostat includes a first loop tube for circulating a coolant at the cryogenic temperature through the magnet coils and a second loop tube for circulating the coolant at the cryogenic temperature through the magnet PCS. The magnetic valve integrated with the second loop tube and configured to selectively couple and decouple the magnet PCS to and from the second loop tube. The magnetic valve includes a first diode and a first solenoid connected between a first terminal and a second terminal, a second diode and a second solenoid connected between the first terminal and the second terminal in parallel with the first diode and the first solenoid, wherein the second diode is arranged antiparallel to the first diode, and a ferromagnetic ball configured to move between an open position and a closed position, where the open position enables flow of the coolant through the second loop tube at the magnet PCS to thermally couple the magnet PCS to the second loop tube, and where the closed position blocks flow of the coolant through the second loop tube at the magnet PCS to thermally decouple the magnet PCS from the second loop tube. The control circuit is configured to apply a control signal having a first polarity to the first and second terminals of the magnetic valve when the magnet PCS is in a closed state and to apply the control signal having a second polarity to the first and second terminals of the magnetic valve when the magnet PCS is in the normal state, where the first polarity is opposite the second polarity. The first solenoid is configured to generate a first magnetic field in response to the control signal having the first polarity, causing the ferromagnetic ball to move toward the first solenoid into the open position enabling the flow of the coolant to lower the temperature of the magnet PCS, and where the second solenoid is configured to generate a second magnetic field in response to the control signal having the second polarity, causing the ferromagnetic ball to move toward the second solenoid into the closed position blocking the flow of the coolant to prevent the magnet PCS from increasing a temperature of the coolant in the first loop tube.

According to another representative embodiment, a system is provided for controlling temperature of a magnet PCS operating in a superconducting magnet system. The includes a heat exchanger configured to disperse heat from to a cryocooler; a loop tube configured to enable flow of coolant to convectively transfer thermal energy generated by the magnet PCS and magnet coils to the heat exchanger; a control circuit configured to generate a control signal having a first polarity and a second polarity opposite the first polarity; and a magnetic valve including a first diode and a first solenoid connected between a first terminal and a second terminal; a second diode and a second solenoid connected between the first terminal and the second terminal in parallel with the first diode and the first solenoid, where the second diode is arranged antiparallel to the first diode; and a ferrous ball configured to move between an open position, enabling flow of the fluid through the loop tube, and a closed position, blocking flow of the fluid through the loop tube. The first solenoid is configured to generate a first magnetic field in response to the control circuit applying the control signal having the first polarity to the first and second terminals, causing the ferrous ball to move toward the first solenoid into the open position, and the second solenoid is configured to generate a second magnetic field in response to the control circuit applying the control signal having the second polarity to the first and second terminals, causing the ferrous ball to move toward the second solenoid into the closed position.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1A is a simplified block diagrams of a magnetic valve in an open position, according to a representative embodiment.

FIG. 1B is a simplified block diagrams of a magnetic valve in a closed position, according to a representative embodiment.

FIG. 2 is a simplified circuit diagram of an H-bridge control circuit for the magnetic valve, according to a representative embodiment.

FIG. 3 is a simplified block diagram of an MR imaging system, including a superconducting magnet system incorporating a magnetic valve, according to a representative embodiment.

FIG. 4 is a simplified block diagram of a superconducting magnet system incorporating a magnetic valve, according to a representative embodiment.

### DETAILED DESCRIPTION

In the following detailed description, for purposes of explanation and not limitation, representative embodiments disclosing specific details are set forth in order to provide a thorough understanding of an embodiment according to the present teachings. Descriptions of known systems, devices, materials, methods of operation and methods of manufacture may be omitted so as to avoid obscuring the description of the representative embodiments. Nonetheless, systems, devices, materials and methods that are within the purview of one of ordinary skill in the art are within the scope of the present teachings and may be used in accordance with the representative embodiments. It is to be understood that the terminology used herein is for purposes of describing particular embodiments only, and is not intended to be limiting. The defined terms are in addition to the technical and scientific meanings of the defined terms as commonly understood and accepted in the technical field of the present teachings.

It will be understood that, although the terms first, second, third etc. may be used herein to describe various elements or components, these elements or components should not be limited by these terms. These terms are only used to distinguish one element or component from another element or component. Thus, a first element or component discussed below could be termed a second element or component without departing from the teachings of the inventive concept.

The terminology used herein is for purposes of describing particular embodiments only, and is not intended to be limiting. As used in the specification and appended claims, the singular forms of terms “a,” “an” and “the” are intended to include both singular and plural forms, unless the context clearly dictates otherwise. Additionally, the terms “comprises,” and/or “comprising,” and/or similar terms when used in this specification, specify the presence of stated features, elements, and/or components, but do not preclude the presence or addition of one or more other features, elements, components, and/or groups thereof. As used herein, the term “and/or” includes any and all combinations of one or more of the associated listed items.

Unless otherwise noted, when an element or component is said to be “connected to,” “coupled to,” or “adjacent to” another element or component, it will be understood that the element or component can be directly connected or coupled to the other element or component, or intervening elements or components may be present. That is, these and similar terms encompass cases where one or more intermediate elements or components may be employed to connect two elements or components. However, when an element or component is said to be “directly connected” to another element or component, this encompasses only cases where the two elements or components are connected to each other without any intermediate or intervening elements or components.

A “computer-readable storage medium” encompasses any tangible storage medium which may store instructions which are executable by a “processor” of a “computing system” or a “controller.” The computer-readable storage medium may be referred to as a non-transitory computer-readable storage medium, to distinguish from transitory media such as transitory propagating signals. The computer-readable storage medium may also be referred to as a tangible computer-readable medium. “Memory” is an example of a computer-readable storage medium. Examples of memory include, but are not limited to RAM memory, registers, and register files.

In some embodiments, a computer-readable storage medium may also be able to store data which is able to be accessed by the processor of the computing system. A computer-readable storage medium may be implemented by any number, type and combination of random-access memory (RAM) and read-only memory (ROM), for example, and may store various types of information, such as software algorithms, artificial intelligence (AI) machine learning models, and computer programs, all of which are executable by a processor, discussed below. The various types of ROM and RAM may include any number, type and combination of non-transitory computer readable storage media, such as a disk drive, flash memory, an electrically programmable read-only memory (EPROM), an electrically erasable and programmable read-only memory (EEPROM), registers, a hard disk, a removable disk, tape, compact disk read only memory (CD-ROM), digital versatile disk (DVD), a floppy disk, Blu-ray disk, a universal serial bus (USB) drive, an optical disk, a magneto-optical disk, or any other form of storage medium known in the art. As used herein, the term non-transitory is to be interpreted not as an eternal characteristic of a state, but as a characteristic of a state that will last for a period. The term non-transitory specifically disavows fleeting characteristics such as characteristics of a carrier wave or signal or other forms that exist only transitorily in any place at any time.

The term “computer readable-storage medium” also refers to various types of recording media capable of being accessed by the computer system or controller via a network or communication link. For example, data may be retrieved over a modem, over the internet, or over a local area network. References to a computer-readable storage medium should be interpreted as possibly being multiple computer-readable storage mediums. Various executable components of a program or programs may be stored in different locations. The computer-readable storage medium may for instance be multiple computer-readable storage medium within the same computer system. The computer-readable storage medium may also be computer-readable storage medium distributed amongst multiple computer systems.

A “processor” as used herein encompasses an electronic component which is able to execute software, a program and/or machine executable instruction, e.g., stored in a memory and/or on a computer readable medium. References to a “computing system,” or a “controller,” or a “control circuit” comprising “a processor” should be interpreted as containing one or more processors and/or processing cores. The processor may be implemented by a general-purpose computer, a central processing unit, a computer processor, a microprocessor, a microcontroller, field programmable gate arrays (FPGAs), application specific integrated circuits (ASICs), a state machine, programmable logic device, or combinations thereof, using any combination of hardware, software, firmware, hard-wired logic circuits, or combinations thereof. The processor may for instance be a multi-core processor. The processor may also refer to a collection of processors within a single computer system or distributed amongst multiple computer systems. The term computing system should also be interpreted to possibly refer to a collection or network of computing devices each comprising one or more processors. Many programs have instructions performed by multiple processors that may be within the same computing system or controller, which may be distributed across multiple computing systems or controllers. The processor may refer to a collection of processors within a single computer system or distributed among multiple computer systems, such as in a cloud-based or other multi-site application.

A “user interface” or “user input device” as used herein is an interface which allows a user to interact with a computer system, a controller and/or a control circuit. A user interface may provide information or data to the user and/or receive information or data from the user. A user interface may enable input from the user to be received by the computer, controller and/or control circuit, and may provide output to the user from the computer, controller and/or control circuit. In other words, the user interface may allow a user to control or manipulate the computer, controller and/or control circuit and the interface may allow the computer, controller and/or control circuit to indicate the effects of the user's control or manipulation. The display of data or information on a display or a graphical user interface is an example of providing information to a user. A user input device of the user interface may include one or more of a touch screen, keyboard, mouse, trackball, touchpad, pointing stick, graphics tablet, joystick, gamepad, webcam, headset, gear sticks, steering wheel, wired glove, wireless remote control, and accelerometer, for example, all of which enable the receiving of information or data from a user.

A “hardware interface” encompasses an interface which enables the processor of a computer system or controller to interact with and/or control an external device and/or apparatus. A hardware interface may allow a processor, for example, to send control signals or instructions to an external computing system and/or apparatus. A hardware interface may also enable a processor to exchange data with an external computer system or controller. Examples of a hardware interface include, but are not limited to: a universal serial bus, IEEE 1394 port, parallel port, IEEE 1284 port, serial port, RS-232 port, IEEE-488 port, Bluetooth connection, Wireless local area network connection, TCP/IP connection, Ethernet connection, control voltage interface, MIDI interface, analog input interface, and digital input interface.

In view of the foregoing, the present disclosure, through one or more of its various aspects, embodiments and/or specific features or sub-components, is thus intended to bring out one or more of the advantages as specifically noted below. For purposes of explanation and not limitation, example embodiments disclosing specific details are set forth in order to provide a thorough understanding of an embodiment according to the present teachings. However, other embodiments consistent with the present disclosure that depart from specific details disclosed herein remain within the scope of the appended claims. Moreover, descriptions of well-known apparatuses and methods may be omitted so as to not obscure the description of the example embodiments. Such methods and apparatuses are within the scope of the present disclosure.

The system for controlling temperature of a magnet persistent current switch (PCS) enables efficient cooling of the magnet PCS, separate from cooling superconducting magnet coils. A cooling system (e.g., cryostat) may be configured to provide cryogenic temperatures to superconducting magnet coils in a superconducting magnet, for example. The cooling system may include a first portion (first stage of a cold head) operating at 40 K and a second portion (second stage of the cold head) operating at 4 K, for example. Generally, embodiments described herein are directed to a magnetic valve that thermally disconnects the magnet PCS from the second portion of the cooling system during energization (ramping) of the superconducting magnet coils, such as an MR imaging magnet, for example. Thermally disconnecting from the second portion of the cooling system is needed to prevent heat from the magnet PCS from overwhelming the cooling system, which maintains the low temperature of the superconducting magnet coils. The magnetic valve may be used for a low-cryogen superconducting magnet, in particular, which has a relatively small helium volume for cooling the superconducting magnet through convective helium flow, as opposed to conductive cooling of a magnet in a conventional helium bath, for example.

As mentioned above, the magnetic valve prevents excessive heat, generated by the magnet PCS when ramping the superconducting magnet, from overloading the cryostat for cooling the superconducting magnet coils. The magnetic valve further enables the magnet PCS to maintain the same temperature as the superconducting magnet coils when the superconducting magnet is in persistent current mode operation. Thus, the various embodiments provide a temperature control system that allows the temperature of the magnet PCS to rise and fall as desired, without straining the cryostat for cooling the superconducting magnet coils.

In addition, embodiments of the magnetic valve require only two electrical wires for operation, as compared to at least four electrical wires in conventional valves. Therefore, the amount of heat introduced to the superconducting magnet by heat leaking in from the room temperature end of the electrical wires is reduced. Also, the valve is operated between open and closed position by simply changing the polarity of the control signal. Additional advantages over conventional valves include reduced connector pin count, reduced electrical wiring in the superconducting magnet, and reduced complexity with regard to running the wiring, for example.

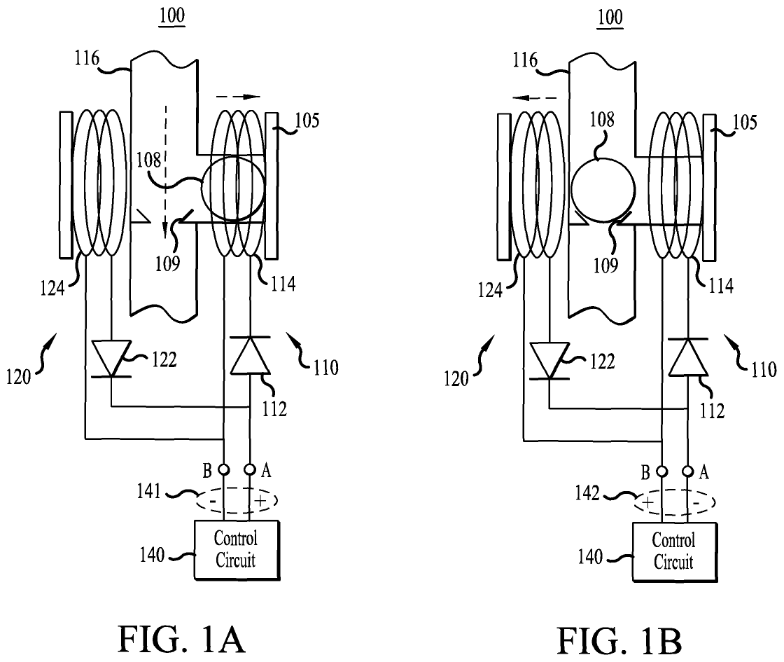

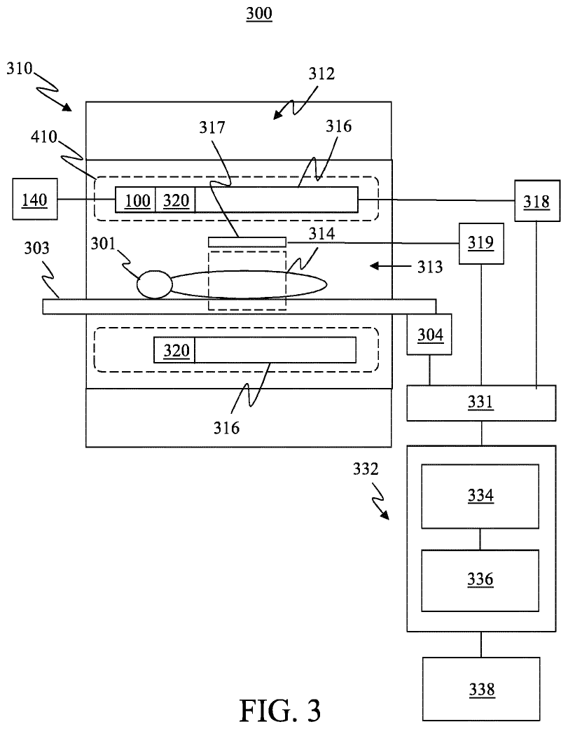

FIGS. 1A and 1B are simplified block diagrams of a magnetic valve in open and closed positions, in accordance with a representative embodiment. The magnetic valve depicted in FIGS. 1A and 1B may be used in a superconducting magnet system, for example, to control flow of a coolant, as discussed below with reference to FIG. 3.

Referring to FIGS. 1A and 1B, magnetic valve 100 is shown integrated with a fluid tube 116, and is configured control fluid flow through the tube 116. The fluid in the tube 116 may be a liquid or a gas, such as liquid helium or gaseous helium, for example.

The magnetic valve 100 includes a housing 105 that contains a ferromagnetic ball 108, and two electromagnets indicated by a first solenoid 114 and a second solenoid 124 positioned outside the tube 116. Although the magnetic valve 100 is described as including the first and second solenoids 114 and 124, it is understood that other types of electromagnets may be incorporated without departing form the scope of the present teachings. The first and second solenoids 114 and 124 are arranged on opposite sides of the tube 116 in order to control movement of the ferromagnetic ball 108 within the housing 105 in response to the first and second solenoids 114 and 124 being selectively energized. The ferromagnetic ball 108 has a diameter greater than an inner diameter of at least a portion of the tube 116, and is configured to move between an open position, enabling flow of the fluid through the tube 116 (indicated by the dashed arrow), and a closed position, blocking flow of the fluid through the tube 116.

In the depicted configuration, the ferromagnetic ball 108 moves to the open position in response to the first solenoid 114 being energized, indicated by the dashed upwardly pointing arrow as shown in FIG. 1A, and the ferromagnetic ball 108 moves to the closed position in response to the second solenoid 124 being energized, indicated by the downwardly pointing dashed arrow as shown in FIG. 1B. In the closed position, the ferromagnetic ball 108 may be arranged in a convex seat 109, for example, to keep the ferromagnetic ball 108 in position. The tube 116 may be formed of a non-magnetic metal, such as copper, aluminum, titanium, zinc, tin or lead, for example, or other non-magnetic material. The ferromagnetic ball 108 may formed of any compatible ferromagnetic material, such as iron, nickel or cobalt, for example.

In the depicted embodiment, the magnetic valve 100 is bi-stable, meaning that once the ferromagnetic ball 108 has moved to one of the open position or the closed position, the first and second solenoids 114 and 124 may be de-energized and the ferromagnetic ball 108 will remain in place (e.g., by the force of gravity) in the convex seat 109.

The magnetic valve 100 further includes a first circuit path 110 and a second circuit path 120, where the first and second circuit paths 110 and 120 are connected in parallel with one another. The first circuit path 110 includes a first diode 112 and the first solenoid 114 connected in series between terminals A and B, and the second circuit path 120 includes a second diode 122 and the second solenoid 124 also connected in series between terminal A and B. A control circuit 140 for the magnetic valve 100 applies voltage across the terminals A and B as control signals for selectively energizing the first and second solenoids 114 and 124 to position the ferromagnetic ball 108, as discussed below. The control signals may have a current of about 100 mA to about 10 A, for example.

Notably, the magnetic valve 100 is operational with only two terminals, terminals A and B. In comparison, conventional magnetic valves include at least four terminals, i.e., two terminals for operating each of multiple electromagnetics. As discussed above, this requires at least twice the amount of electrical wiring needed through the system of which the magnetic valve is a part. Thus, stated differently, the depicted embodiment reduces the amount of wiring by at least half, which not only simplifies designs and reduces costs, but also reduces the amount of heat that leaks in to the system, of which the magnetic valve 100 is a part (e.g., superconducting magnet), through the wires connected to the respective terminals.

The second diode 122 is arranged antiparallel to the first diode 112, meaning that they permit current flow in opposite directions, respectively. That is, in the depicted configuration, the first diode 112 has an anode connected to terminal A and a cathode connected to the first solenoid 114 such that current is only able to flow from terminal A, through the first solenoid 114, to terminal B, thereby energizing the first solenoid 114 (generating a first magnetic field) while the second solenoid 124 is de-energized. The second diode 122 has an anode connected to terminal B and a cathode connected to the second solenoid 124 such that current is only able to flow from terminal B, through the second solenoid 124, to terminal A, thereby energizing the second solenoid 124 (generating a second magnetic field) while the first solenoid 114 is de-energized.

Whether the current flows through the first diode 112 or the second diode 122 depends on the polarity of the control signal output by the control circuit 140. In the depicted configuration, when the control circuit 140 outputs the control signal with a first polarity 141 (e.g., positive (+) applied to terminal A and negative (−) applied to terminal B), current flows through the first diode 112 and the first solenoid 114, which generates the first magnetic field in response to the control signal. This causes the ferromagnetic ball 108 to move toward the first solenoid 114 into the open position as shown in FIG. 1A. Because the second diode 122 arranged antiparallel to the first diode 112, no current flows to the second solenoid 124, which therefore remains de-energized. When the control circuit 140 outputs the control signal with a second polarity 142 (e.g., positive (+) applied to terminal B and negative (−) applied to terminal A), current flows through the second diode 122 and the second solenoid 124, which generates the second magnetic field in response to the control signal. This causes the ferromagnetic ball 108 to move toward the second solenoid 124 into the closed position as shown in FIG. 1B. Because the first diode 112 is arranged antiparallel to the second diode 122, no current flows to the first solenoid 114, which therefore remains de-energized. Accordingly, the magnetic valve 100 is operated between open and closed positions based on the polarity of the control signal provided by the control circuit 140.

As mentioned above, the magnetic valve 100 is bi-stable, so both the first and second solenoids 114 and 124 may be de-energized following the change of position of the ferromagnetic ball 108. In alternative configurations, one of the first and second solenoids 114 and 124 may remain energized to hold the ferromagnetic ball 108 in place, without departing from the scope of the present teachings.

The control circuit 140 may be implemented by any circuit capable of changing polarity of an output signal. For example, the control circuit 140 may be an H-bridge, although any compatible circuit for changing polarity may be incorporated without departing from the scope of the present teachings.

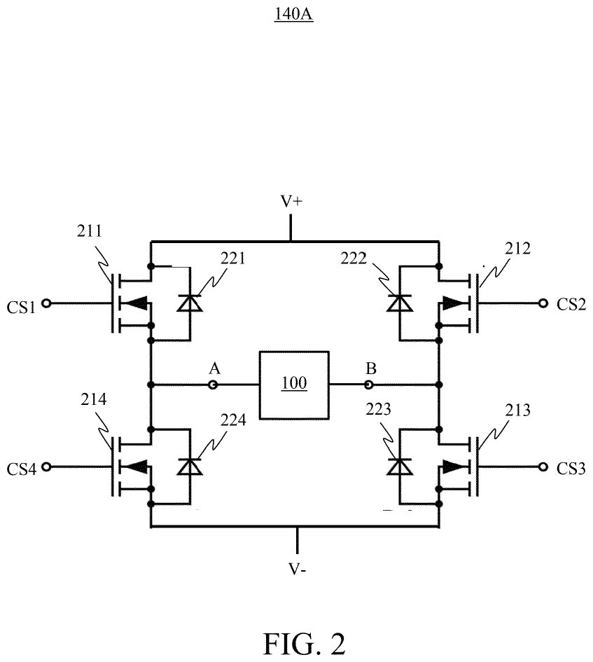

FIG. 2 is a simplified circuit diagram of an H-bridge control circuit for the magnetic valve, according to a representative embodiment.

Referring to FIG. 2, control circuit 140A comprises an illustrative H-bridge circuit. In particular, the control circuit 140A includes a first transistor 211 and a second transistor 212 connected between positive voltage V+ and negative voltage V− (e.g., common or ground), and a third transistor 213 and a fourth transistor 214 also connected between the positive voltage V+ and the negative voltage V−. Each of the first to fourth transistors 211-214 is depicted a metal oxide silicon field-effect transistor (MOSFET), although it is understood that they may be any type of compatible FET or other type of transistor, such as a bipolar junction transistor (BJT), without departing from the scope of the present teachings. Flyback diodes are connected between sources and drains of each of the first to fourth transistors 211-214. That is, a first diode 221 is connected between the source and drain of the first transistor 211, a second diode 222 is connected between the source and drain of the second transistor 212, a third diode 223 is connected between the source and drain of the third transistor 213, and a fourth diode 224 is connected between the source and drain of the fourth transistor 214. The gates of the first transistor 211, the second transistor 212, the third transistor 213, and the fourth transistor 214 are connected to first control signal CS1, second control signal CS2, third control signal CS3, and fourth control signal CS4, respectively, for controlling the states of the transistors. The first to fourth control signals CS1-CS4 may be provided by control logic, e.g., from a state machine implemented by a controller (not shown), such as a microcontroller, a field programmable gate array (FPGA), an erasable programmable logic device (EPLD) and/or an application-specific integrated circuit (ASIC), for example, as would be apparent to one of ordinary skill in the art.

The control circuit 140A is connected to terminal A of the magnetic valve 100 between the first transistor 211 and the fourth transistor 214, and to terminal B of the magnetic valve 100 between the second transistor 212 and the third transistor 213. Changing the polarity of the control signal at the terminals A and B is accomplished by turning on and off different pairs of transistors. For example, in the depicted configuration, the first polarity 141 is output by turning on the first transistor 211 and the third transistor 213, and turning off the second transistor 212 and the fourth transistor 214. The second polarity 142 is output by turning on the second transistor 212 and the fourth transistor 214, and turning off the first transistor 211 and the third transistor 213.

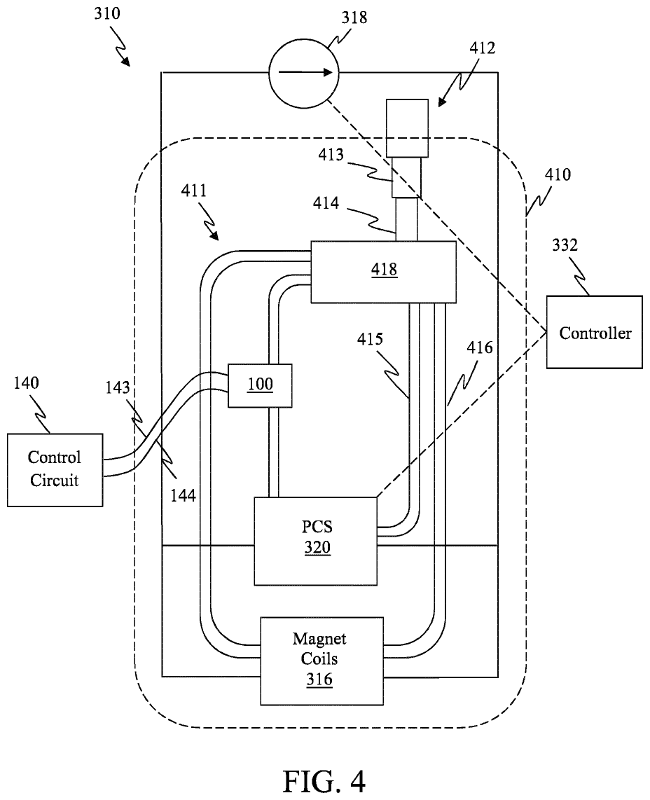

Because of the reduced number terminals (terminals A and B), and thus the corresponding reduced number of electrical wires needed to operate the magnet valve 100, the magnet valve 100 is useful in systems that require very low operating temperatures (e.g., cryogenic temperatures), since fewer electrical wires cause less heat leakage, with other factors being equal. For example, as discussed above, superconducting magnet systems require cryogenic temperature of about 4K to be maintained in the superconductive state. Such superconducting magnet systems are incorporated in magnetic resonance (MR) imaging systems, an example of which is discussed below with reference to FIGS. 3 and 4. When the magnet valve 100 is implemented in such an MR imaging system, the electrical wires would be run through the superconducting magnets, conducting in high (room) temperatures, so the fewer electrical wires the better.

FIG. 3 is a simplified block diagram of an MR imaging system, including a superconducting magnet system incorporating a magnetic valve according to a representative embodiment. The following description of the MR imaging system is intended to be illustrative and not limiting.

Referring to FIG. 3, MR imaging system 300 includes a superconducting magnet system 310 that includes a superconducting magnet 312 with a bore 313. The superconducting magnet 312 may be a cylindrical magnet, for example, although different types of superconducting magnets may be incorporated, such as a split cylindrical magnet and an open magnet, without departing from the scope of the present teachings. An imaging zone 314 is provided in the bore 313 where the magnetic field generated by operation of the superconducting magnet 312 is strong and uniform enough to perform the magnetic resonance imaging. A subject 301 is placed on a support 303 and positioned within the bore 313 to be imaged during the MR imaging procedure. The support 303 may be attached to an actuator 304 (optional) configured to move the support 303, so that the subject 301 may be moved through the imaging zone 314. Accordingly, a larger portion of the subject 301 or the entire subject 301 may be imaged.

The superconducting magnet 312 includes a set of magnet coils 316, which may be magnetic field gradient coils, configured to acquire magnetic resonance data for spatially encoding magnetic spins within the imaging zone 314. In the depicted embodiment, the magnet coils 316 are likewise cylindrical, and are therefore indicated in cross-section form above and below the bore 313. A magnet coil power supply 318 supplies current to the magnet coils 316. Electrical current from the power supply 318 may be controlled as a function of time, and may be ramped or pulsed, for example. It is understood that the superconducting magnet 312 may include one or more magnet coils 316 in various implementations, e.g., to enable spatially encoding in three orthogonal spatial directions, without departing from the scope of the present teachings.

In order to operate in a persistent current mode, the superconducting magnet 312 includes a closed superconducting circuit with a superconducting loop. The superconducting circuit is interrupted to allow the power supply 318 to drive electrical current into the magnet coils 316, which may be referred to as ramping the superconducting magnet 312 (or the magnet coils 316) to the operating at-field state. To this end, the superconducting magnet 312 further includes a magnet persistent current switch (PCS) 320, which is operable to interrupt the superconducting circuit for ramping the superconducting magnet 312. In order to reach cryogenic temperatures, the superconducting magnet 312, including the magnet PCS 320, are cooled by a cryostat 410, which includes convective cooling loops 411 for circulating coolant, discussed below with reference to FIG. 4.

The magnet PCS 320 is heated by a PCS heater (not shown) to cause it to enter a resistive state, referred to as a normal state. In the normal state, the magnet PCS 320 still has a relatively small electrical resistance, although this is effectively an open compared to the absence of resistance in the superconducting magnet 312 in the superconducting state. Only when the magnet PCS 320 is in the normal state can a voltage be developed across it to get current into the magnet coils 316. The electrical resistance of the magnet PCS 320 in the normal state, together with the heat applied to the magnet PCS 320 causing it to enter the normal state, cause the temperature of the magnet PCS 320 to increase during the ramping process. To prevent this increased temperature from spreading to the magnet coils 316 via the coolant circulated in the convective cooling loops 411, the magnetic valve 100 is arranged with the magnet PCS 320 to remove (thermally disconnect) the magnet PCS 320 from the convective cooling loops 411 during the ramping process, under control of the control circuit 140.

The MR imaging system 300 further includes RF coil 317 located within the bore 313. The RF coil 317 is configured to manipulate orientations of magnetic spins within the imaging zone 314, and to receive RF transmissions from spins also within the imaging zone 314. The RF coil 317 may represent dedicated transmit and receive antennas or may contain multiple transmit and receive coil elements. The RF coil 317 is shown connected to an RF transceiver 319, which transmits and receives RF signals to and from the RF coil 317 during the MR imaging procedure. In various configurations, the RF coil 317 and the RF transceiver 319 may be replaced by separate transmit and receive coils and separate transmitters and receivers, for example.

The actuator 304, the power supply 318, and the RF transceiver 319 are connected to a hardware interface 331 and a controller 330. The controller 330 includes a processor 334, memory 336, and a user interface 338. The memory 336 represents one or more non-transitory memories and/or computer-readable storage mediums, discussed above. The memory 336 may store pulse sequence instructions, which are executed by the processor 334 for performing the MR imaging procedure, as would be apparent to one of ordinary skill in the art. The memory 336 may also include data storage for storing magnetic resonance image data and/or reconstructed magnetic resonance images acquired during the MR imaging procedure.

The hardware interface 331 enables the controller 330 to interact with, control and/or exchange data with at least the actuator 304, the power supply 318, and the RF transceiver 319. The processor 334 is representative of one or more processors, discussed above. The user interface 338 enables a user or user to interact with the controller 330, receiving input from the user to be received by the processor 334 and providing output to the user from the processor 334. That is, the user interface 338 may provide information or data to the user and/or receive information or data from the user, as discussed above.

FIG. 4 is a simplified block diagram of a superconducting magnet system incorporating a magnetic valve, according to a representative embodiment.

Referring to FIG. 4, a portion of the superconducting magnet system 310 is shown, which includes the magnet coils 316, the magnet PCS 320 connected in parallel with the magnet coils 316, and the power supply 318 (shown as a current source, for purposes of illustration). The magnet coils 316 and the magnet PCS 320 are in the cryostat 410 of the superconducting magnet system 310 in order to limit temperatures. That is, the magnet coils 316 and the magnet PCS 320 may be maintained at low temperature by a cryocooler 412 in (and attached to) the cryostat 410. The cryocooler 412 has a first stage 413 that maintains the temperature of a thermal shield (not shown) that envelops the magnet coils 316 and the magnet PCS 320 at about 40 K, and a second stage 414 that maintains the temperature of the magnet coils 316 and the magnet PCS 320 (in its closed state) at about 4 K. A portion of the cryocooler 412 may be accessible from outside the cryostat 410. The power supply 318 may be permanently or temporarily connected to electrical contacts outside the cryostat 410.

The cryostat 410 includes the convective cooling loops 411, which includes a heat exchanger 418 and first and second loop tubes 415 and 416. The first and second loop tubes 415 and 416 are configured carry coolant, such as liquid or gaseous helium, at a temperature of about 4 K. The first loop tube 415 runs through the magnet coils 316 to cool the magnet coils 316 to the superconducting state. The second loop tube 416, which may be substantially the same as the tube 116, discussed above, runs through the magnet PCS 320 and the magnetic valve 100. The heat exchanger 418 is permanently connected to, or in thermal contact with, the second stage 414 of the cryocooler 412 and is configured to disperse heat to the cryocooler 412. The cryostat 410 may also include another convective cooling loop (not shown), which includes another loop tube and another heat exchanger, which is permanently connected to, or in thermal contact with, the first stage 413 of the cryocooler 412, for carrying coolant at a temperature of about 40 K, mentioned above. Generally, the other convective cooling loop is more robust than the convective cooling loops 411, and thus handles the majority of the cooling of the superconducting magnet system 310 to superconducting temperatures, as would be apparent to one of ordinary skill in the art. The magnetic valve 100 need not be thermally disconnected from the 40 K convective cooling loop during ramping, since this convective cooling loop is configured to handle the increased temperature of the magnetic valve 100.

The controller 330 may be implemented by one or more processors executing instructions, e.g., stored in memory and/or on a computer readable medium, as discussed above. In the depicted embodiment, the controller 330 controls the power supply 318 and the state of the magnet PCS 320, via signals indicated by dashed lines, to enable ramping the magnet coils 316, to put the superconducting magnet 312 in persistent current mode, and to ramp down the superconducting magnet 312, e.g., in response to instructions given by an user.

The control circuit 140 controls operation of the magnetic valve 100 in order to control the temperature of the magnet PCS 320 by selectively blocking and enabling flow of coolant (e.g., gaseous or liquid helium) through the second loop tube 416. The control circuit 140 is connected to the magnetic valve 100 through a single pair of electrical wires, indicated as electrical wires 143 and 144, which run through the cryostat 410. Since there are only two electrical wires 143 and 144, less heat leaks through the electrical wires 143 and 144 as compared to conventional systems requiring multiple pairs of electrical wires, as discussed above. Therefore, the two electrical wires 143 and 144 have less effect on the temperature of the cryostat 410. It is understood that the functionality of the control circuit 140 may be incorporated within the controller 330, or implemented separately from the controller 330, without departing from the scope of the present teachings.

More particularly, the controller 330 controls the magnet PCS 320 to selectively enter the normal state for ramping the superconducting magnet 312 to the operating current, and to selectively enter the closed state for maintaining the operating current (in the persistent current mode). The magnet PCS 320 may include composite superconducting wire made of superconducting filaments inside a copper matrix, the same as or similar to the superconducting wire used in the magnet coils 316. As mentioned above, in an embodiment, the magnet PCS 320 may be one of the magnet coils 316. Like other superconducting wire, this composite superconducting wire acts as a “normal” conductor at high temperature and as “superconductor” at cryogenic temperatures. When the magnet PCS 320 is in the closed (superconducting) state, it is able to carry the magnet current while the superconducting magnet system 310 is in the persistent current mode. When the magnet PCS 320 is in the normal state, it cannot carry the magnet current, and is controlled to interrupt the superconducting circuit. The magnet PCS 320 may be switched to the normal state by heating, e.g., using a PCS heater (not shown). However, as discussed above, the magnet PCS 320 has a small (normal) resistance in the normal state, which is high enough that a ramping voltage can be applied across the magnet PCS 320 for ramping the magnet coils 316 to the operating current. When the magnet PCS 320 transitions from the closed state to the normal state, and the operating current runs in the magnet coils 316, as well as the PCS 320.

In addition, the control circuit 140 controls the magnetic valve 100 to open and close, e.g., depending on action required by the user. For example, when the magnet PCS 320 is in the normal state for ramping up the superconducting magnet 312 to the operating current in the superconducting state, the magnetic valve 100 is closed to stop the flow of coolant through the second loop tube 416, thereby thermally disconnecting the magnet PCS 320 from heat exchanger 418. As discussed above, the magnet PCS 320 is heated up to enter the normal state, and also generates heat by conducting some current in the normal state, without overloading the second stage 414 of the cryocooler 412. That is, by stopping the flow of the coolant through the magnet PCS 320, the increased temperature of the magnet PCS 320 will not increase the temperature of the coolant in the second loop tube 416, thereby sparing the heat exchanger 418 from having to remove this additional heat to maintain the 4 K temperature. When the magnet PCS 320 is in the closed state for operating the superconducting magnet 312 in the persistent current mode or ramping down the superconducting magnet 312, the magnetic valve 100 is opened to enable the flow of coolant from the second loop 416 through the magnet PCS 320, thereby thermally connecting the magnet PCS 320 to heat exchanger 418 via the second loop tube 416 to provide additional cooling to ensure that the magnet PCS 320 stays in superconducting state.

In an embodiment, the control circuit 140 may send control signals having different pluralities to open and close the magnet valve 100, as discussed above. When the control signal has the first polarity 141, it passes through the first diode 112 and the first solenoid 114, energizing the first solenoid 114. The energized first solenoid 114 creates a first magnetic field that draws the ferromagnetic ball 108 toward the first solenoid 114, opening the magnet valve 100 to permit the coolant in the second loop tube 416 to flow through the magnet PCS 320. When the control signal has the second polarity 142, it passes through the second diode 122 and the second solenoid 124, energizing the second solenoid 124. The energized second solenoid 124 creates a second magnetic field that draws the ferromagnetic ball 108 toward the second solenoid 124, closing the magnet valve 100 to prevent the coolant in the second loop tube 416 from flowing through the magnet PCS 320, thermally disconnecting the magnet PCS 320 from the second loop tube 416 and the heat exchanger 418.

The second stage 414 of the cryocooler 412 is able to bring the magnet coils 316 and the magnet PCS 320 to the desired cryogenic temperature of about 4 K, although it has a limited capacity for absorbing power. Thus, heat coming from the magnet PCS 320 in the normal state would otherwise overload the cryocooler 412. As discussed above, when the power supply 318 is connected across the magnet PCS 320 in its normal state, most of the current will flow into the magnet coils 316, and some current will flow through the normal, resistive wires of the magnet PCS 320. Once current flowing through the superconducting magnet coils 316 has reached its target value (target current), the controller 330 controls the magnet PCS 320 to enter the closed state, e.g., by turning off the PCS heater, enabling the magnet PCS 320 to conduct the operating current while magnet coils 316 operate in the persistent current mode with effectively zero resistance, after ramping down the power supply 318. This may be referred to as a closed superconducting circuit.

As discussed above with regard to the tube 116, the second loop tube 416 (as well as the first loop tube 415) may be formed of a non-magnetic metal, such as copper, aluminum, titanium, zinc, tin or lead, for example, or other non-magnetic material. The second loop tube 416 is hermetically sealed, and the coolant contained in the second loop tube 416 may be helium gas or helium liquid, for example, for enabling the convective transfer of thermal energy between the magnet PCS 320 and the heat exchanger 418. Other types of gas and/or liquid coolant may be incorporated without departing from the scope of the present teachings. The magnetic valve 100 is configured to open and close the second loop tube 416 in order to selectively enable and block flow of the coolant, respectively. When the magnetic valve 100 is open, the coolant can flow through the second loop tube 416, the magnet PCS 320 and the heat exchanger 418 in order to dissipate the heat. When the magnetic valve 100 is closed, the flow of the coolant through the second loop tube 416 is blocked. In various embodiments, the magnet valve 100 be implemented using a ball valve containing the ferromagnetic ball 108 having a diameter greater than an inner diameter of the opening of the second loop tube 416. The first and second solenoids 114 and 124 (electromagnets) control placement of the ferromagnetic ball 108 within the opening of the second loop tube 416 or other orifice within the ball valve to selectively block the second loop tube 416 by activating and deactivating magnetic fields based on polarity of the control signal, as discussed above.

In an embodiment, superconducting magnet system 310 includes an additional magnetic valve (not shown) integrated with the second loop tube 416 between the magnet PCS 320 and the heat exchanger 418. The additional magnetic valve is positioned on a return portion of the second loop tube 416, such that the additional magnetic valve is likewise configured to selectively block the flow of the coolant through the second loop tube 416, e.g., when ramping the superconducting magnet 312, as discussed above with regard to the magnetic valve 100. The magnetic valve 100 and the additional magnetic valve may be operated substantially simultaneously, which increases efficiency of the convective cooling loops 411, because substantially simultaneous operation eliminates possibility of convective flow between the magnet PCS 320 and the heat exchanger 418 inside only one of the two legs of the second cooling tube 416. It also improves reliability of the system where two magnetic valves are redundant, which avoids possible expensive and time consuming repair if the magnetic valve 100 were to fail.

Although the system for controlling temperature of a persistent current switch has been described with reference to several exemplary embodiments, it is understood that the words that have been used are words of description and illustration, rather than words of limitation. Changes may be made within the purview of the appended claims, as presently stated and as amended, without departing from the scope and spirit of the system for controlling temperature of a persistent current switch in its aspects. Although the system for controlling temperature of a persistent current switch has been described with reference to particular means, materials and embodiments, the system for controlling temperature of a persistent current switch is not intended to be limited to the particulars disclosed; rather the system for controlling temperature of a persistent current switch extends to all functionally equivalent structures, methods, and uses such as are within the scope of the appended claims.

Although the present specification describes components and functions that may be implemented in particular embodiments with reference to particular standards and protocols, the disclosure is not limited to such standards and protocols. Such standards are periodically superseded by more efficient equivalents having essentially the same functions. Accordingly, replacement standards and protocols having the same or similar functions are considered equivalents thereof.

The illustrations of the embodiments described herein are intended to provide a general understanding of the structure of the various embodiments. The illustrations are not intended to serve as a complete description of all of the elements and features of the disclosure described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is provided to comply with 37 C.F.R. § 1.72 (b) and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The preceding description of the disclosed embodiments is provided to enable any person skilled in the art to practice the concepts described in the present disclosure. As such, the above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

1. A magnetic valve integrated with a tube for controlling flow of a fluid through the tube, the magnetic valve comprising:
a first diode and a first solenoid connected between a first terminal and a second terminal;
a second diode and a second solenoid connected between the first terminal and the second terminal in parallel with the first diode and the first solenoid, wherein the second diode is arranged antiparallel to the first diode; and
a ferrous ball configured to move between an open position, enabling flow of the fluid through the tube, and a closed position, blocking flow of the fluid through the tube,
wherein the first solenoid is configured to generate a first magnetic field in response to a control signal having a first polarity being applied to the first and second terminals, causing the ferrous ball to move toward the first solenoid into the open position, and
wherein the second solenoid is configured to generate a second magnetic field in response to the control signal having a second polarity being applied to the first and second terminals, causing the ferrous ball to move toward the second solenoid into the closed position, wherein the second polarity is opposite to the first polarity of the control signal.

2. The magnetic valve of claim 1, wherein the fluid comprises liquid helium.

3. The magnetic valve of claim 1, wherein the fluid comprises gaseous helium.

4. The magnetic valve of claim 1, wherein the each of the second control signal has a current of about 100 mA to about 10 A.

5. The magnetic valve of claim 1, wherein the tube comprises at least one of copper, aluminum, titanium, zinc, tin or lead, and the ferromagnetic ball comprises at least one of iron, nickel or cobalt.

6. The magnetic valve of claim 1, further comprising a seat arranged in the tube, wherein the ferromagnetic ball is arranged in the seat when in the closed position, so that the ferromagnetic ball is held in place in the seat by gravity when the second solenoid stops generating the second magnetic field.

7. A magnetic resonance (MR) imaging system comprising:
(i) superconducting magnet system configured to provide an MR magnetic field to enable MR imaging, the superconducting magnet system comprising:
a plurality of magnet coils configured to generate the MR magnetic field in a superconducting state,
a magnet persistent current switch (PCS) configured to enter a normal state during ramping of the plurality of magnet coils to an operating current in the superconducting state, wherein a temperature of the magnet PCS increases in the normal state, and
a cryostat configured to provide a cryogenic temperature to the plurality of magnet coils and the magnet PCS, wherein the cryostat includes a first loop tube for circulating a coolant at the cryogenic temperature through the plurality of magnet coils and a second loop tube for circulating the coolant at the cryogenic temperature through the magnet PCS;
(ii) a magnetic valve integrated with the second loop tube and configured to selectively couple and decouple the magnet PCS to and from the second loop tube, the magnetic valve comprising:
a first diode and a first solenoid connected between a first terminal and a second terminal,
a second diode and a second solenoid connected between the first terminal and the second terminal in parallel with the first diode and the first solenoid, wherein the second diode is arranged antiparallel to the first diode, and
a ferromagnetic ball configured to move between an open position and a closed position, wherein the open position enables flow of the coolant through the second loop tube at the magnet PCS to thermally couple the magnet PCS to the second loop tube, and wherein the closed position blocks flow of the coolant through the second loop tube at the magnet PCS to thermally decouple the magnet PCS from the second loop tube; and
(iii) a control circuit configured to apply a control signal having a first polarity to the first and second terminals of the magnetic valve when the magnet PCS is in a closed state and to apply the control signal having a second polarity to the first and second terminals of the magnetic valve when the magnet PCS is in the normal state, wherein the first polarity is opposite the second polarity,
wherein the first solenoid is configured to generate a first magnetic field in response to the control signal having the first polarity, causing the ferromagnetic ball to move toward the first solenoid into the open position enabling the flow of the coolant to lower the temperature of the magnet PCS, and
wherein the second solenoid is configured to generate a second magnetic field in response to the control signal having the second polarity, causing the ferromagnetic ball to move toward the second solenoid into the closed position blocking the flow of the coolant to prevent the magnet PCS from increasing a temperature of the coolant in the first loop tube.

8. The MR imaging system of claim 7, wherein the control circuit comprises an H-bridge configured to provide the first drive signal and the second drive signal having the opposite polarities.

9. The MR imaging system of claim 7, wherein the magnet PCS comprises one magnetic coil of the plurality of magnet coils.

10. The MR imaging system of claim 7, wherein the loop tube is configured to circulate the coolant at coolant temperature of about 4K.

11. The MR imaging system of claim 10, wherein the cryostat further includes another loop tube for circulating additional coolant through the plurality of magnet coils and the magnet PCS at a coolant temperature of about 40K, wherein the another loop tube is not integrated with the valve such that the another loop tube continues to remove heat from the magnet PCS via the additional coolant during the ramping of the plurality of magnet coils to the operating current.

12. The MR imaging system of claim 7, wherein the ferromagnetic ball is arranged in a convex seat when in the closed position, so that the ferromagnetic ball is held in place in the convex seat by gravity when the second solenoid is controlled to stop generating the second magnetic field.

13. The system of claim 7, wherein the coolant comprises gaseous helium.

14. The system of claim 7, wherein the superconducting magnet system further comprises a PCS heater configured to heat the magnet PCS, causing the magnet PCS to enter the normal state.

15. A system for controlling temperature of a magnet persistent current switch (PCS) operating in a superconducting magnet system, the system comprising:
a heat exchanger configured to disperse heat to a cryocooler;
a loop tube configured to enable flow of coolant to convectively transfer thermal energy generated by the magnet PCS and a plurality of magnet coils to the heat exchanger;
a control circuit configured to generate a control signal having a first polarity or a second polarity opposite the first polarity; and
a magnetic valve comprising:
a first diode and a first solenoid connected between a first terminal and a second terminal;
a second diode and a second solenoid connected between the first terminal and the second terminal in parallel with the first diode and the first solenoid, wherein the second diode is arranged antiparallel to the first diode; and
a ferrous ball configured to move between an open position, enabling flow of the fluid through the loop tube, and a closed position, blocking flow of the fluid through the loop tube,
wherein the first solenoid is configured to generate a first magnetic field in response to the control circuit applying the control signal having the first polarity to the first and second terminals, causing the ferrous ball to move toward the first solenoid into the open position, and
wherein the second solenoid is configured to generate a second magnetic field in response to the control circuit applying the control signal having the second polarity to the first and second terminals, causing the ferrous ball to move toward the second solenoid into the closed position.

16. The system of claim 15, wherein the coolant comprises gaseous helium.

17. The system of claim 15, wherein the control circuit comprises an H-bridge.

18. The system of claim 15, wherein the loop tube is configured to circulate the coolant at coolant temperature of about 4K.

19. The system of claim 15, wherein the magnet PCS comprises one magnetic coil of the plurality of magnet coils.

20. The system of claim 15, further comprises a PCS heater configured to heat the magnet PCS, causing the magnet PCS to enter a normal state.
